(19) United States
(12) Patent Application Publication
(10) Pub. No.: US 2026/0067593 A1
(43) Pub. Date: Mar. 5, 2026

(54) PIXEL CIRCUIT AND IMAGE SENSOR

(71) Applicant: HUAWEI TECHNOLOGIES CO., LTD., Shenzhen (CN)

(72) Inventor: Makoto Monoi, Tokyo (JP)

(73) Assignee: HUAWEI TECHNOLOGIES CO., LTD., Shenzhen (CN)

(21) Appl. No.: 19/384,792

(22) Filed: Nov. 10, 2025

Related U.S. Application Data
(63) Continuation of application No. PCT/CN2024/072531, filed on Jan. 16, 2024.

(51) Int. Cl. H04N 25/77; G01J 1/44; H04N 25/57

(52) U.S. Cl. CPC H04N 25/77; G01J 1/44; G01J 2001/446; H04N 25/57

(57) ABSTRACT

Embodiments of the present disclosure provide example pixel circuits and image sensors. One example pixel circuit includes a photodiode, a measuring circuit that measures a light amount according to a current output from one end of the photodiode, and a gate circuit provided between the photodiode and the measuring circuit. The pixel circuit is supplied with a recharge signal to set one end of the photodiode to a predetermined potential. The gate circuit is configured to connect the photodiode and the measuring circuit such that the measuring circuit measures the light amount at a plurality of time points in a single cycle of the recharge signal.

### CROSS-REFERENCE TO RELATED APPLICATIONS

This application is a continuation of International Application No. PCT/CN2024/072531, filed on Jan. 16, 2024, which is hereby incorporated by reference in its entirety.

### TECHNICAL FIELD

The present disclosure relates to a pixel circuit and an image sensor, and in particular to a pixel circuit and an image sensor that detect light using a photodiode.

### BACKGROUND

Traditionally, image sensors in which pixels including avalanche photodiodes (APDs) are arranged have been known. In such an image sensor, a photon incident on the APD generates a photoelectric charge, which causes avalanche multiplication. Thus, it is possible to detect faint light.

In recent years, in image sensors using avalanche photodiodes for capturing images, Single Photon Avalanche Diode (SPAD) sensors, which are image sensors especially using SPAD, have been in use. Since the SPAD sensor can count incoming photons one by one at high speed, it is possible to read electrical signals without noise, for example, to take photos at high speed.

However, conventional SPAD sensors consume more power due to the high number of electronic avalanches of SPAD pixels. On the other hand, reducing the power consumption of the SPAD sensor reduces its dynamic range. In addition, when trying to expand the dynamic range in the conventional SPAD sensor, a pixel size will increase and an electrical signal cannot be read quickly.

### SUMMARY

The present disclosure has been made in view of the above-described problems, and the object is to provide a pixel circuit and an image sensor that have a wider dynamic range than the conventional image sensor and can read electrical signals at high speeds while suppressing power consumption.

According to a first aspect, the present disclosure provides a pixel circuit, comprising: a photodiode; a measuring circuit configured to measure a light amount in accordance with a current output from one end of the photodiode; and a gate circuit provided between the photodiode and the measuring circuit, wherein a recharge signal is supplied to set one end of the photodiode to a predetermined potential; and wherein the gate circuit is configured to connect the photodiode and the measuring circuit such that the measuring circuit measures the light amount at a plurality of time points in a single cycle of the recharge signal.

In some implementations, a photodiode and a measuring circuit are connected to measure a light amount at a plurality of time points in a single cycle of the recharge signal. Therefore, while suppressing power consumption, it has the wider dynamic range than the conventional pixel circuit, and it is possible to read electrical signals at high speed. Also, a pixel size of the pixel circuit can also be reduced. In addition, it is possible to read electrical signals at a high speed.

In some implementations, the gate circuit is configured to connect the photodiode and the measuring circuit at the same cycle as a cycle of the recharge signal.

In some implementations, since the photodiode and the measuring circuit are connected at the same cycle as the cycle of the recharge signal, a signal for controlling the gate circuit can be generated based on the recharge signal.

In some implementations, the gate circuit is configured to connect the photodiode and the measuring circuit at a sampling phase different from the recharge signal.

In some implementations, since the photodiode and the measuring circuit are connected at different sampling phases from the recharge signal, a signal for controlling the gate circuit can be generated based on the recharge signal.

In some implementations, the measuring circuit includes a plurality of counters, and the gate circuit is configured to connect the photodiode and each of the plurality of counters such that the plurality of counters perform counting operations at different points in time.

In some implementations, since the photodiode and the measuring circuit are connected at different sampling phases from the recharge signal, individual counters can measure light of different intensities.

In some implementations, the gate circuit comprises a plurality of switches, and wherein each of the plurality of switches is configured to connect the photodiode and one of the plurality of counters.

In some implementations, since the photodiode and the measuring circuit are connected at different sampling phases from the recharge signal, the switch of the gate circuit can be controlled such that individual counters measure light of different intensities.

In some implementations, the counter is configured to output a count value after the recharge signal is supplied multiple times.

In some implementations, since the count values to be counted for each sampling phase are output separately, one linear output characteristic can be obtained by combining them.

In some implementations, the measuring circuit is configured to sum count values from a plurality of photodiodes to generate one output.

In some implementations, because count values from a plurality of photodiodes are summed to generate one output, a plurality of count values can be added to enhance sensitivity with a small pixel size.

According to a second aspect, the present disclosure provides an image sensor in which the above-described pixel circuits are arranged in a two-dimensional lattice.

### BRIEF DESCRIPTION OF THE DRAWINGS

To describe the technical solutions in the embodiments more clearly, the following briefly describes the accompanying drawings needed for describing the embodiments. Apparently, the accompanying drawings in the following description depict merely some of the possible embodiments, and a person of ordinary skill in the art may still derive other drawings, without creative efforts, from these accompanying drawings, in which:

FIG. 1 is a diagram illustrating an operating principle of a conventional SPAD sensor, wherein (a) shows an example of a cross-section of an SPAD, (b) shows a configuration of a pixel circuit of the SPAD sensor using the SPAD shown in (a), and (c) shows a relationship between a voltage and a count value at a particular location of the pixel circuit shown in (b).

FIG. 2A illustrates a relationship between illuminance and count values in an example of a conventional image sensor.

FIG. 2B illustrates a relationship between illuminance and count values in an example of a conventional image sensor.

FIG. 2C illustrates a relationship between illuminance and count values in an example of a conventional image sensor.

FIG. 2D illustrates a relationship between illuminance and count values in an example of a conventional image sensor.

FIG. 3 is a diagram illustrating an example configuration of a sensor substrate of an image sensor according to an implementation of the present disclosure.

FIG. 4 is a diagram illustrating an example configuration of a circuit board of an image sensor according to an implementation of the present disclosure.

FIG. 5 is a diagram illustrating an example configuration of a pixel circuit according to an implementation of the present disclosure.

FIG. 6 is a timing diagram for describing an example signal output operation in the pixel circuit shown in FIG. 5.

FIG. 7 is a diagram illustrating an example frame configuration of a pixel signal according to an implementation of the present disclosure.

FIG. 8 is a diagram illustrating an example offset cycle of a count gate according to an implementation of the present disclosure.

FIG. 9 is a diagram showing an example simulation result of a relationship of count values to the number of photons, according to an implementation of the present disclosure.

FIG. 10 is a diagram illustrating a conventional pixel circuit configuration.

FIG. 11 is a timing diagram for describing an output operation of a signal in the pixel circuit shown in FIG. 10.

FIG. 12 is a diagram to illustrate another output operation of a signal in the pixel circuit shown in FIG. 10, where (a) is a timing diagram and (b) shows a relationship between illuminance and a count value.

FIG. 13 is a diagram illustrating example simulation results of SNR characteristics of an image sensor relative to a light amount according to an implementation of the present disclosure.

FIG. 14 is a diagram showing example results of calculating power consumed by SPAD pixels according to an implementation of the present disclosure.

FIG. 15 is a diagram illustrating an example configuration of a pixel circuit according to an implementation of the present disclosure.

FIG. 16 is a timing diagram for describing an example signal output operation in the pixel circuit, according to an implementation of the present disclosure.

FIG. 17 is a diagram illustrating components of an example pixel circuit according to an implementation of the present disclosure.

FIG. 18A is a diagram illustrating an example configuration of a pixel circuit in mode (1), according to an implementation of the present disclosure.

FIG. 18B is a diagram illustrating an example of an actual connection of the pixel circuit shown in FIG. 18A.

FIG. 19A is a diagram illustrating an example configuration of a pixel circuit in mode (2), according to an implementation of the present disclosure.

FIG. 19B is a diagram illustrating an example of an actual connection of the pixel circuit shown in FIG. 19A.

FIG. 20A is a diagram illustrating an example configuration of a pixel circuit in mode (3), according to an implementation of the present disclosure.

FIG. 20B is a diagram illustrating an example of an actual connection of the pixel circuit shown in FIG. 20A.

FIG. 21 is a diagram illustrating dynamic ranges of image sensors in modes (1) to (3).

### DESCRIPTION OF EMBODIMENTS

To make persons skilled in the art understand the technical solutions in the present disclosure better, the following describes the technical solutions in some embodiments of the present disclosure with reference to the accompanying drawings in the modes of the present disclosure. Apparently, the described embodiments are merely a part rather than all of the embodiments of the present disclosure. All other embodiments obtained by persons of ordinary skill in the art based on the embodiments of the present disclosure without creative efforts shall fall within the protection scope of the present disclosure.

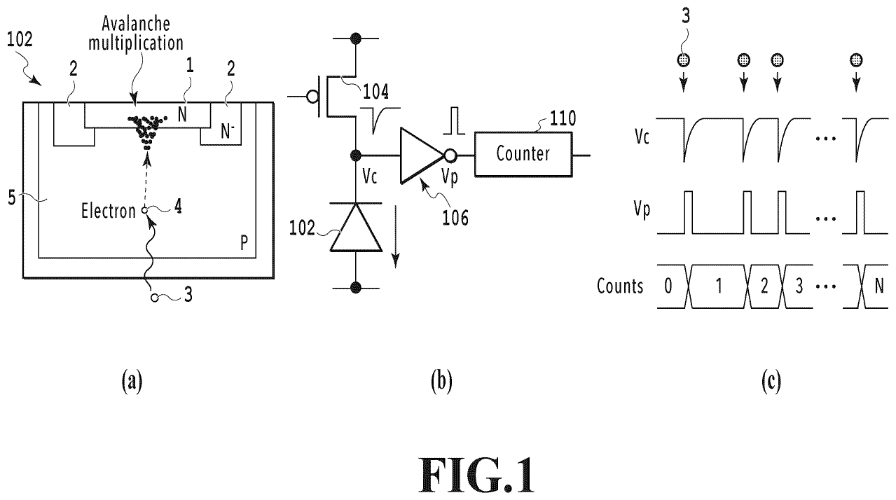

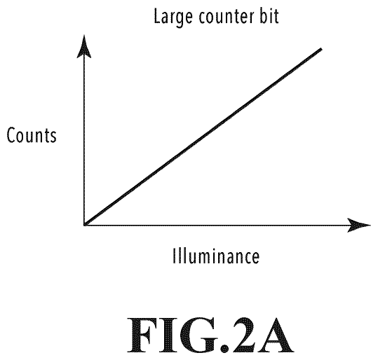

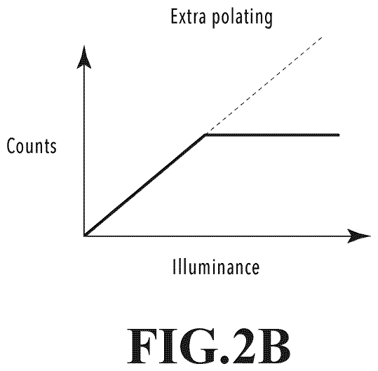

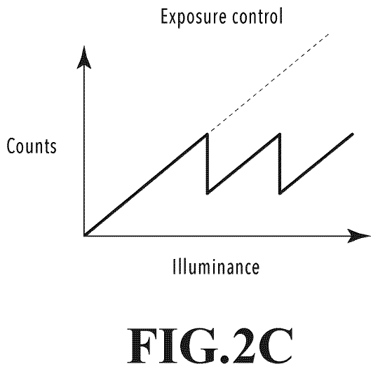

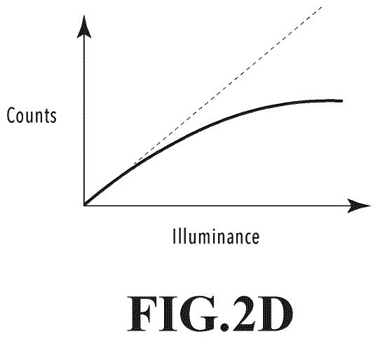

First, with reference to FIGS. 1 and 2A-2D, a principle and an operation control method of an image sensor (also referred to as “SPAD sensor”) using a general SPAD will be described.

FIG. 1 is a diagram illustrating the operating principle of the conventional SPAD sensor. In FIG. 1, (a) shows an example of a cross-section of the SPAD, (b) shows a configuration of a pixel circuit of an SPAD sensor using the SPAD shown in (a), and (c) shows the relationship between a voltage and a counter value at a particular location of the pixel circuit shown in (b).

The SPAD 102 shown in FIG. 1 (a) is joined with a P-type semiconductor layer (hereinafter referred to as the “P layer”) 5 and an N-type semiconductor layer (hereinafter referred to as the “N layer”) 1, in which the N layer 1 is surrounded by N-type well layers 2. The pixel circuit shown in FIG. 1 (b) functions as a photo counter. The SPAD 102 is connected to a counter 110 via an inverter 106. A line which includes a switch 104 for supplying a recharge signal is connected between the SPAD 102 and the inverter 106. Here, the potential of the cathode of the SPAD 102 is represented by Vc, and the potential of the output of the in inverter 106 is represented by Vp.

An inverse bias voltage is applied by electrodes provided on the upper and lower sides of the SPAD 102 such that the potential of the N layer 1 is higher than the potential of the P layer 5. The reverse bias voltage applied to the SPAD is slightly higher than a breakdown voltage. When a photon 3 enters the Player 5 from the underside of FIG. 1 (a), it is absorbed in the Player 5 to form a pair of holes with an electron 4. This electron 4 is amplified by avalanche multiplication, which lowers the voltage between the electrodes. When the voltage between the electrodes drops to the breakdown voltage, the charge is released from the N layer 1. Then, when the recharge signal is supplied and the voltage is increased, the pixel circuit returns to a state where photons can be detected (recharge operation).

Thus, as shown in FIG. 1 (c), when the photon 3 enters the SPAD, electrons are emitted from the N layer 1, the voltage Vc drops, and then the pixel circuit is returned to its original potential by the recharge signal. An output waveform of this voltage is output to the counter 110 as a waveform shaped voltage Vp by the inverter 106, and the count value stored in the counter 110 is incremented.

Next, a relationship between the illuminance and the count value in the conventional image sensor operation control method will be described.

FIG. 2A illustrates a relationship between illuminance and count values in an example of a conventional image sensor. Usually, there is a proportional relationship between the illuminance and the count value. Therefore, in order to broaden the dynamic range sufficiently, the number of count bits per pixel may be increased. However, increasing the number of count bits enlarges the pixel circuit and the pixel size. Also, power consumption increases with the increase in the number of count bits.

In an example shown in FIG. 2B, the exposure time of the image sensor is interrupted in order to expand the dynamic range. Then, the count value after the exposure is interrupted is determined by extrapolation. However, if a subject changes during exposure, values cannot be obtained appropriately by extrapolation with this motion control method. Also, when this motion control is performed, the number of pixel counts is still large, and the size of the pixel is not reduced. As a result, the power consumption is high, and the electrical signal cannot be read at high speed.

In an example shown in FIG. 2C, multiple exposures have been made to increase the dynamic range by varying the exposure time. However, the number of pixel counts is still large and the pixel size cannot be reduced. As a result, the power consumption is high, and the electrical signal cannot be read at high speed.

An example shown in FIG. 2D illustrates changes in count values in an operation control method using a clustered multi-cycle clocked recharging technique. In this method, the dynamic range can be expanded by shifting cycles of recharging in different multiple cycles. However, in this case, the power consumption increases because the number of recharges increases. Also, the pixel count is still large and the pixel size is not reduced. Furthermore, the electrical signal cannot be read at high speed. Yet further, since the recharge signals of different cycles are mixed in one counter, the overall output becomes non-linear.

In the above-described example of conventional motion control, since the number of electronic avalanches of SPAD pixels is high, the power consumption of the image sensor is large. Also, because the number of bits of the counter needed for each pixel is large, the pixel size increases.

Further, since all the count values are integrated into one frame and output, information of the count values cannot be obtained at a high speed.

Furthermore, in the case of the method of interrupting or changing the exposure time as shown in FIGS. 2B and 2C, the image is damaged when the subject changes during the exposure time. Yet further, when a plurality of different cycles are combined in a single counter as shown in FIG. 2D, the output values become non-linear because all count values are mixed and output with a single counter.

Some implementations of the present disclosure expand a dynamic range by controlling an input of a signal to a counter without making changes to a recharge signal. According to this method, power consumption can be suppressed while expanding the dynamic range. Also, a pixel size can also be reduced. In addition, it is possible to read electrical signals at a high speed.

Hereinafter, specific example embodiments of the present disclosure will be described in detail with reference to the drawings.

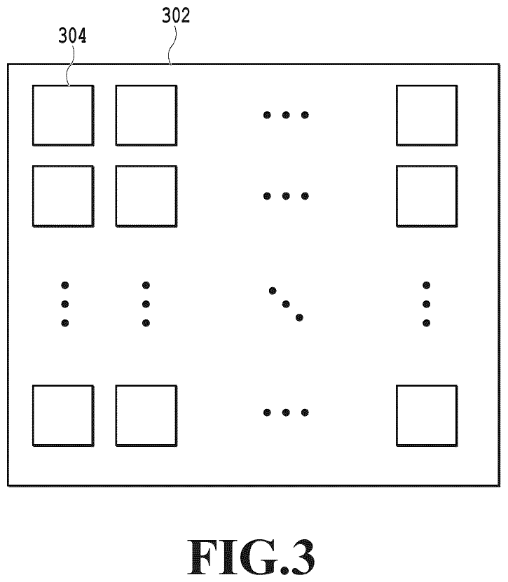

FIG. 3 is a diagram illustrating an example of a configuration of a sensor substrate of an image sensor according to an embodiment. The image sensor has a light-receiving part 304 of a pixel circuit arranged in a two-dimensional shape on a sensor substrate 302.

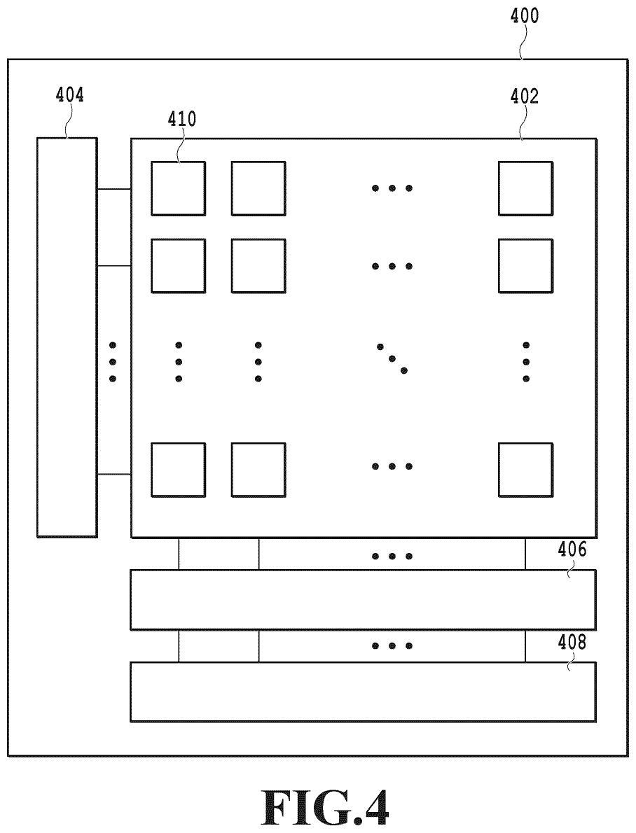

FIG. 4 is a diagram illustrating an example configuration of a circuit board of the image sensor. The circuit board 400 includes a logical array part 402 in which the logical part 410 of the pixel circuit is arranged in the two-dimensional shape corresponding to the light-receiving part 304. The logical array part 402 is provided with a vertical control part 404, a horizontal control part 406, and a signal processing unit 408. Each of these logical parts 410 is also connected via a signal line with a light-receiving part 304 at a corresponding location. A circuit comprising the light-receiving part 304 and the logical part 410 corresponding to the light-receiving part acts as a pixel circuit that generates a pixel signal of one pixel in image data.

A vertical synchronization signal is input to the vertical control part 404 and a horizontal synchronization signal is input to the horizontal control part 406. An exposure control signal is input to the logical array part 402. The vertical control part 404 and the horizontal control part 406 control the logical part 410 in synchronization with these signals.

The vertical control part 404 synchronizes with the vertical synchronization signal to select rows in order. The logical part 410 counts the number of photons in the exposure period and outputs a signal indicating the count value as a pixel signal. The horizontal control part 406 synchronously selects the columns in order to output the pixel signal in synchronization with the horizontal synchronization signal. The signal processing unit 408 performs predetermined signal processing, such as filtering, on the image data consisting of the pixel signals. This signal processing unit 408 outputs the processed image data. Embodiments of the present disclosure are made by supplying control signals from the vertical control part 404 and the horizontal control part 406 to the pixel circuit.

### First Embodiment

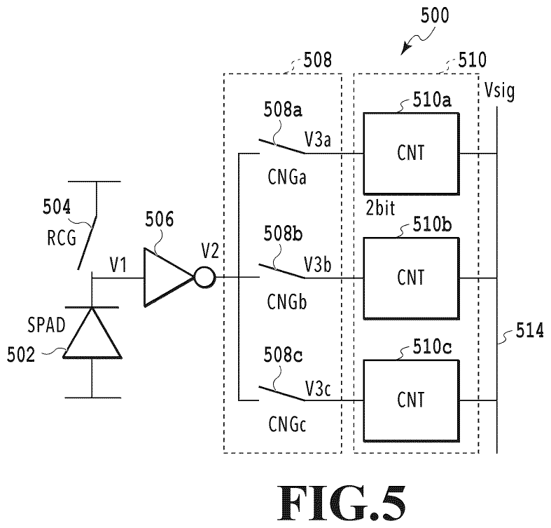

Referring now to FIG. 5, the first embodiment of the present disclosure will be described. The pixel circuit 500 shown in FIG. 5 comprises an SPAD 502, a measuring part 510 that measures the amount of light in response to the current output from the cathode of the SPAD 502, and a gate part 508 provided between the SPAD 502 and the measuring part 510. The gate part 508 has three switches. These switches serve as gates for the measuring part 510 and are referred to as count gates in the following description. The measuring part 510 has 2-bit counters 510a, 510b, and 510c.

The SPAD 502 is connected to the inverter 506. A count gates 508a, 508b and 508c are provided between the inverter 506 and the counters 510a, 510b and 510c, respectively. ON/OFF operations of the count gates 508a, 508b, and 508c are controlled by the count gate signals CNGa, CNGb, and CNGc, respectively, supplied from lines not shown.

The counters 510a-510c are connected to an output line 514. The count signal output to the output line 514 is represented by Vsig.

A recharge switch 504 for supplying a recharge signal RCG is provided between a cathode of the SPAD 502 and the inverter 506. The cathode side of the SPAD 502 is supplied with the recharge signal RCG to set the cathode side to a predetermined potential. The gate part 508 is configured to connect the SPAD 502 and the measuring part 510 such that the measuring part 510 measures the light amount at multiple points in time in a single cycle of the recharge signal RCG. Here, the potential of the cathode of the SPAD 502 is represented by V1, and the potential of the output of the inverter 106 is represented by V2. Also, the potential of the inputs of the counters 510a, 510b and 510c are represented by V3a, V3b, V3c.

The SPAD 502 corresponds to the light-receiving part 304 of FIG. 3, and other components correspond to the logical part 410 of FIG. 4.

Output operation of signals by the pixel circuit 500 will be described. The voltage of the pixel is reset in a constant cycle by the recharge signal RCG. The reset results in a higher voltage V1. When a photon enters the SPAD 502, a charge is generated and the voltage V1 is lowered. The voltage V1 is inverted by the inverter 506 to output a signal of the voltage V2. The voltage V2 is sampled by the count gates 508a-508c and counted by the separate counters 510a-510c. The counters 510a-510c are configured to output a signal Vsig including count values after the recharge signal RCG has been supplied multiple times. In some implementations of the present embodiment, the count values are output as the signal Vsig to the output line 514 for every three RCG pulses.

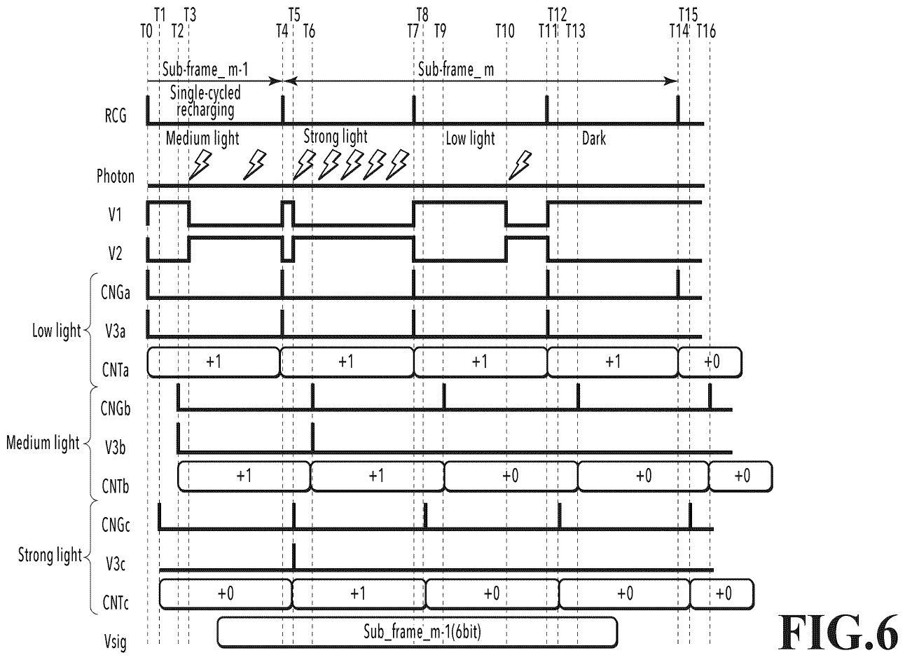

FIG. 6 is a timing diagram for describing signal output operations in the pixel circuit shown in FIG. 5. The recharge signal RCG is output at T0, T4, T7, T11 and T14 at a constant cycle. A count value sampling is performed every three cycles that the recharge signals RCG are supplied to configure one subframe. FIG. 6 shows the (m−1)th subframe and the m-th subframe.

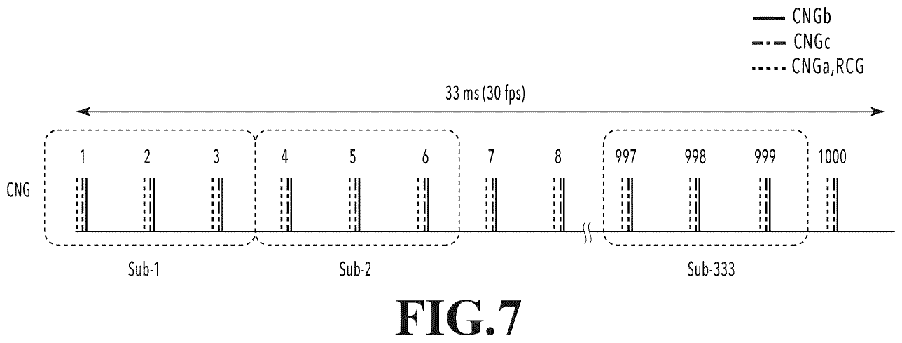

FIG. 7 illustrates an example of a frame configuration of a pixel signal. In the embodiment shown in FIG. 7, a main frame rate is set at 30 frames per second (fps), one main frame is 33 ms, and 1000 recharges are performed. Because subframes are output every three recharge cycles, one mainframe contains 333 subframes. The frame rate of the subframe is 1000 fps. Thus, it is possible to detect changes in objects at high speed by output per subframe.

At the i-th subframe, if the count values of counters 510a, 510b, and 510c are Sub-ia, Sub-ib, and Sub-ic, respectively, then the count values of the three counters in one frame are represented by:

$${\sum }_{i = 1}^{333} Sub - ia , {\sum }_{i = 1}^{333} Sub - ib , and {\sum }_{i = 1}^{333} Sub - ic .$$

These count values may be expressed in 10 bits, respectively. The count value of the mainframe is obtained by integrating these values, and this value is output as the signal Vsig.

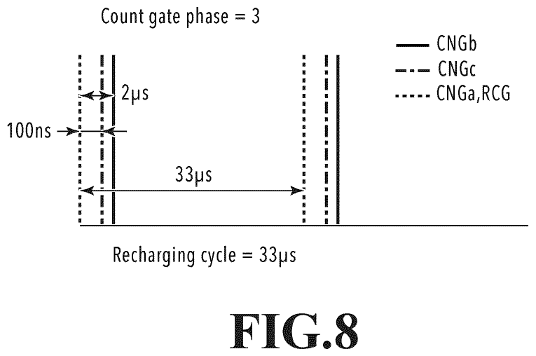

FIG. 8 shows an example of offset cycles at the count gate. The gate part 508 is configured to connect the SPAD 502 and the measuring part 510 at the same cycle as the cycle of the recharge signal RCG. The gate part 508 is also configured to connect the SPAD 502 and the measuring part 510 at a different sampling phase from the recharge signal RCG. There are three sampling phases made at the count gate, and the sampling cycle is 33 μs which is the same as the cycle of the recharge signal RCG. The sampling phase of the count gate signal CNGa is just before the recharge signal RCG. The sampling phase of the count gate signal CNGb is 2 μs behind the recharge signal RCG, and the sampling phase of the count gate signal CNGc is 100 ns behind the recharge signal RCG. The sampling phase of the count gate can take any value. Accordingly, the number of counters and the number of count gates used for sampling also vary.

Returning to FIG. 6, output operations at times T0 to T16 will be described. A lightning-shaped marks on the axis labeled Photon indicate timings when a single photon is incident on the pixel circuit. As for intervals of the recharge signal RCG, a light of intermediate intensity is irradiated between T0 and T4, and two photons are incident from T3. A strong light is irradiated between T4 and T7, and five photons are incident from T5. A weak light is irradiated between T7 and T11, and one photon is incident at T10. No light is incident between T11 and T14.

The recharge signal RCG causes the voltage V1 to be high. When light is incident on the SPAD 502 at T3, T5 and T10, the voltage V1 changes from High to Low. The voltage V2 is the value obtained by inverting the voltage V1.

The gate part 508 is configured to connect the SPAD 502 and each of the counters 510a-510c such that the counters 510a-510c count at different points in time.

More specifically, the count gates 508a, 508b and 508c are configured to connect the SPAD 502 and the counters 510a, 510b and 510c, respectively. Each of the count gate signals CNGa-CNGc are pulse signals with the same cycle as the recharge signal RCG and different sampling phases from the recharge signal RCG. An ON operation by the count gate using the count gate signal is started at a timing individually offset from the recharge signal RCG as a reference. For example, at the m-th subframe, the count gate 508a initiates the ON operation from T4, the count gate 508b initiates the ON operation from T6, and the count gate 508c initiates the ON operation from T5.

In the example shown in FIG. 6, the count value outputs the signal Vsig for each pulse of the three recharge signal RCGs. The information of the count value at the counters 510a-510c is output to the output line 514 and integrated into the total 6-bit value Sub_frame_m−1. This information is included in one subframe and is output as the signal Vsig.

The count gate signal CNGa becomes High at T0, T4, T7, T11 and T14, and the voltage V3a becomes High. At T0, T4, T7 and T11, the voltage V2 is High and the counter 510a performs a counting operation. At T14, the voltage V2 is Low, and the counter 510a does not perform the counting operation. Thus, the count value of the counter 510a in three recharges is 3.

The count gate signal CNGb becomes High at T2, T6, T9, T13, and T16. At T2 and T6, the voltage V2 is High. The voltage V3b becomes High and the counter 510b performs the counting operation. At T9, T13 and T16, the voltage V2 is Low and the counter 510b does not perform the counting operation. Therefore, the count value of the counter 510b in the three recharges is 2.

The count gate signal CNGc becomes High at T1, T5, T8, T12, and T15. At T5, the voltage V2 is High. The voltage V3c becomes High and the counter 510c performs the counting operation. At T1, T8, T12 and T15, the voltage V2 is Low and the counter 510c does not perform the counting operation. Thus, the count value of the counter 510c in the three recharges is 1.

In the above operations, the counter 510a counts the strong light, the intermediate light, and the weak light. Also, the counter 510b counts the strong light and intermediate light. Furthermore, the counter 510c only counts the strong light. Thus, individual counters can measure different intensities of light.

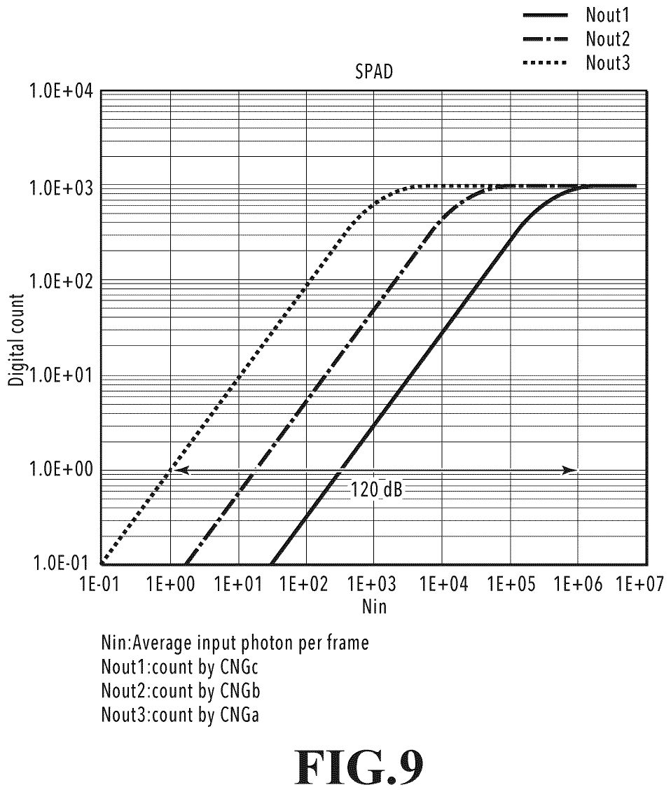

FIG. 9 is a diagram showing simulation results of the relationship of count values to the number of photons. Ni is an average of the number of input photons per frame. In the three curves, Nout1 indicates the count number by the count gate signal CNGc. Also, Nout2 indicates the count number by the count gate signal CNGb, and Nout3 indicates the count number by the count gate signal CNGa. According to the operation control method of the pixel circuit described above, because different frames are generated for each sampling phase, it is possible to obtain an almost linear output depending on the amount of light. The final generated mainframe is acquired by combining the mainframes of each sampling phase.

In the configuration shown in FIG. 5, if the recharge pulse of the recharge signal RCG records the count values three times, a 2-bit counter for each pixel is needed for each sampling phase of the count gate. Thus, the size of the pixels can be reduced because the number of bits is sufficiently small compared to the conventional counters. The number of pulses recorded at the counter may be any number of times, and for example, it may take any value from one to a south and times. The number of counts also varies according to the number of pulses.

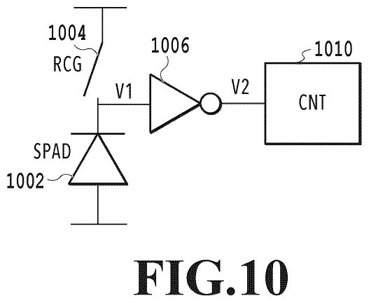

FIG. 10 is a diagram illustrating the configuration of the conventional pixel circuit. An SPAD 1002 is connected to a counter 1010 via an inverter 1006. A line including a recharge switch 1004 for supplying a recharge signal RCG is connected between the SPAD 1002 and the inverter 1006. Here, the potential of the cathode of the SPAD 1002 is indicated by V1, and the potential of the output of the inverter 1006 is indicated by V2.

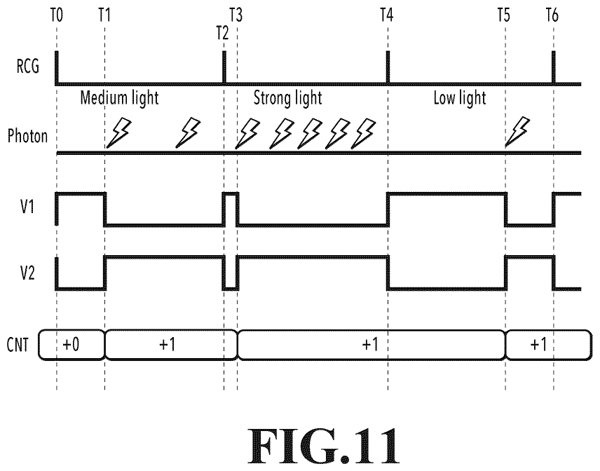

FIG. 11 is a timing diagram for describing output operations of signals in the pixel circuit shown in FIG. 10. The operation of the pixel circuit from time T0 to T6 will be described below.

The recharge signal RCG is output at T0, T2, T4, T6 at a constant cycle. The recharge signal RCG causes the voltage V1 to be high. When light is incident on the SPAD 1002 at T1, T3, and T5, the voltage V1 changes from High to Low. The voltage V2 is output as an inverted value of the voltage V1.

As for intervals of the recharge signal RCG, the intermediate light is irradiated between T0 and T2, and two photons from T1 are incident. The strong light is irradiated between T2 and T4, and five photons from T3 are incident. The weak light is irradiated between T4 and T6, and one photon is incident at T5. The count values are counted at T1, T3, and T5. Since the number of resets is limited by the recharge signal RCG, the power consumption for reset does not increase. However, in one cycle, the dynamic range of the image sensor cannot be expanded because the count value only increases by 1 regardless of the intensity of the light.

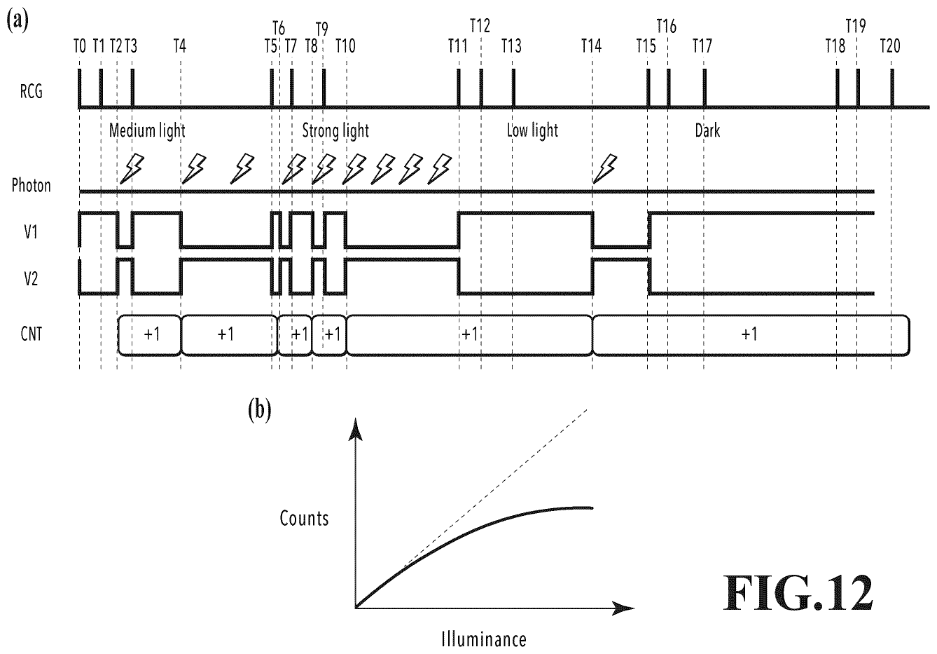

FIG. 12 is a timing diagram for illustrating another output operation of a pixel signal in the conventional pixel circuit shown in FIG. 10. The operation of the pixel circuit from time T0 to T19 will be described below.

FIG. 12 (a) is an example of an operation control method of a pixel circuit employing conventional multi-cycle clock charging. The recharge signal RCG is normally in the OFF state and the signals at T0, T5, T11, T15 and T18 constitute the first pulse of a constant cycle. Also, the signals at T1, T7, T12, T16, and T19 constitute the second pulse with the constant cycle offset from TO. Further, the signals at T3, T9, T13, T17, and T20 constitute the third pulse with the constant cycle offset from TO. Since the counter 1010 performs the counting operation at the rise of the voltage V2, it is performed at T2, T4, T6, T8, T10, and T14. In the example shown in FIG. 12 (a), the dynamic range can be extended by performing the recharge operation by combining different cycles of offset values. However, since the number of recharges increases in the example shown in FIG. 12 (a), the power consumption is greater compared to the present embodiment. Also, because the count values are mixed and output by the single counter, the output becomes non-linear as shown in FIG. 12 (b), and fast detection cannot be performed if the subject changes.

In contrast, in the image sensor using the pixel circuit according to the present embodiment as shown in FIG. 9, a wide dynamic range of 120 dB can be obtained from the count value of 1 to the maximum saturation amount. Since the count values of each sampling phase counted by the counters 510a, 510b and 510c are output separately, they can be combined to obtain one linear output characteristic as a whole.

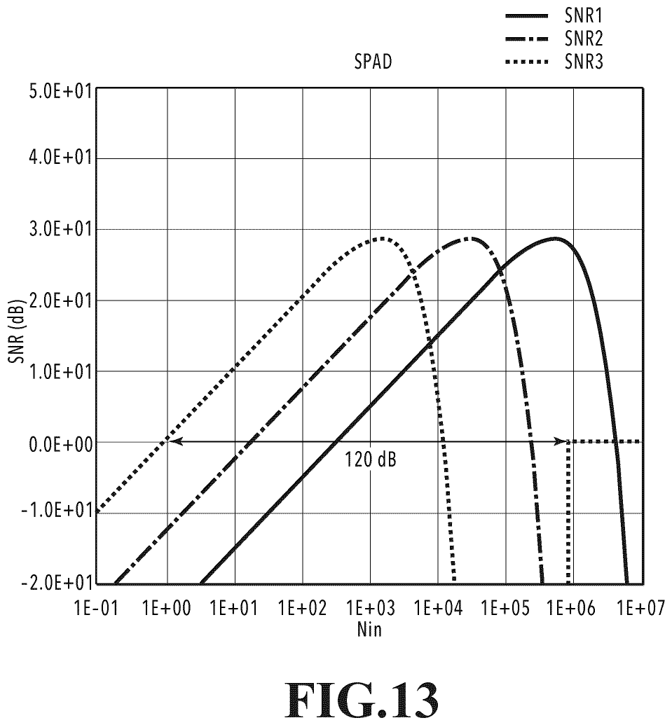

FIG. 13 shows a simulation result of SNR (signal-to-noise ratio) characteristics relative to the light intensity of the image sensor according to an implementation of the present disclosure. Here, SNR1 is an SN ratio of the output from the counter 510c, SNR2 is the SN ratio of the output from the counter 510b, and SNR3 is the SN ratio of the output from the counter 510a. According to FIG. 13, the ON/OFF control of each phase in the count gate signal CNGa-CNGc results in the sufficient SN ratio up to 28 dB.

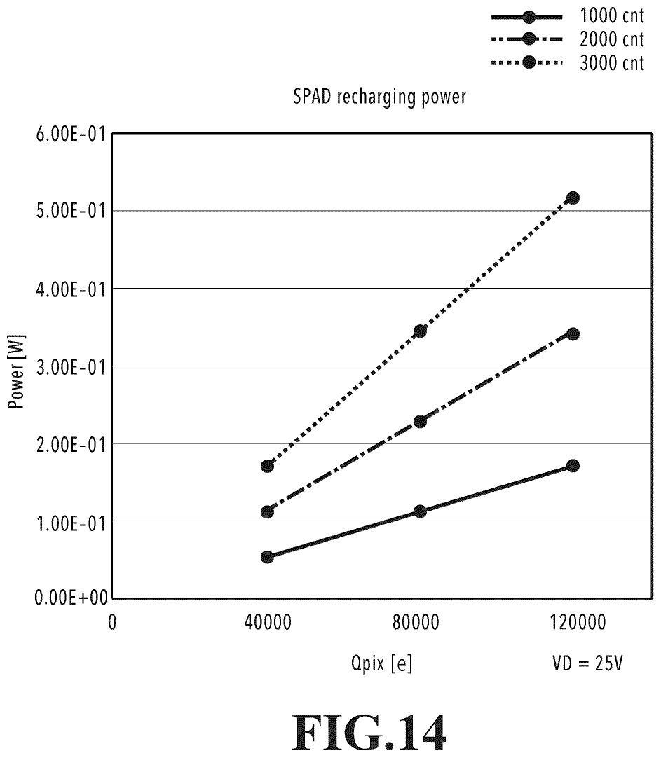

FIG. 14 shows a result of calculating power consumed by resetting SPAD pixels with 12 M pixels and a frame rate of 30 fps. In FIG. 14, the horizontal axis is the number of electrons generated at one time (Qpix) and the vertical axis is the power consumption (W). The SPAD pixels consume power each time they are reset. Power was calculated for three cases: 1000 (1000ct), 2000 (2000ct), and 3000 (3000ct) resets per second. As for the curve at 1000 ct, it is understood that the power is suppressed to less than 2000 mW over a light intensity of 4000 to 12000 (e).

As described above, according to some implementations of the present disclosure, a fast time-varying subject can be detected, and a low-power, small-pixel-size image sensor with the wide dynamic range can be provided. This image sensor can also be applied to noise-free night vision imaging.

Also, by adding a mechanism to change the sampling phase of the photoelectric converted signal for each counter, the dynamic range can be expanded without increasing the power consumption needed for recharging.

Further, by counting the photoelectrically converted signals at separate counters for each sampling phase, a linear output is obtained for each amount of light.

Furthermore, by outputting the count value to one frame multiple times, it is possible to quickly detect changes in the object and reduce the number of bits of counters needed for each pixel.

Yet further, by outputting a short subframe at a high speed, the pixel circuit can be simplified and the pixel size can be reduced.

### Second Embodiment

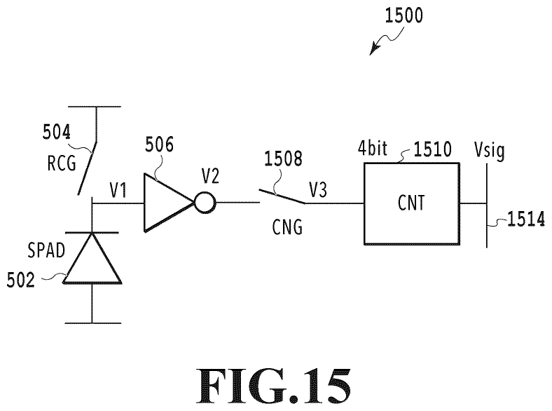

An example second embodiment of the present disclosure will now be described with reference to FIG. 15. FIG. 15 is a diagram illustrating a configuration of a pixel circuit 1500 according to an implementation of the present disclosure. The SPAD 502 is connected to the inverter 506. Between the inverter 506 and a 4-bit counter 1510, a line is connected that includes a count gate 1508 which is a gate part. The count gate signal for controlling the count gate 1508 is represented by CNG. Here, the potential of the cathode of the SPAD 1502 is represented by V1, and the potential of the output of the inverter 506 is represented by V2. Also, the potential of the input of the counter 1510 is represented by V3.

The counter 1510 is a measuring part connected to an output line 1514. The count signal output to the output line 1514 is represented by Vsig.

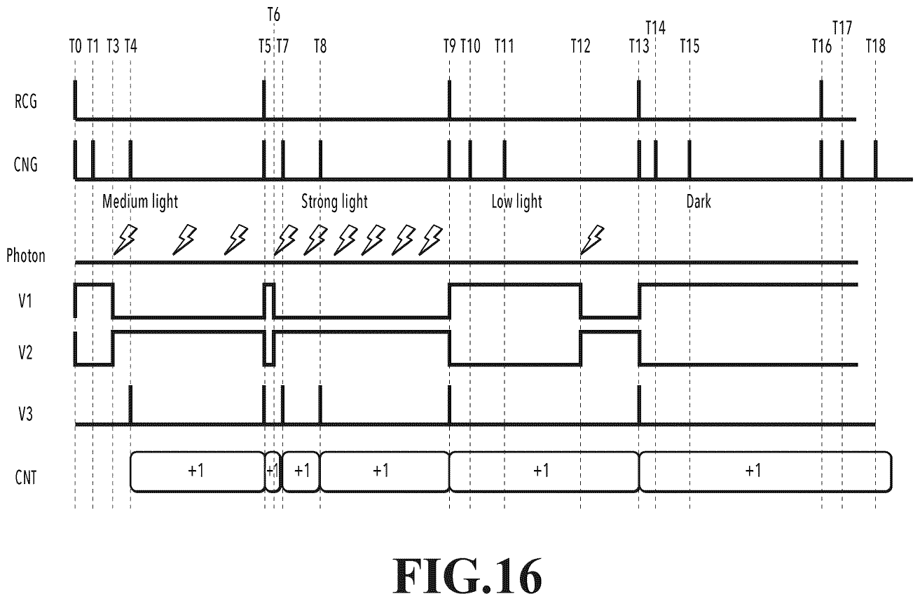

FIG. 16 is a timing diagram to illustrate output operations of the pixel circuit 1500. The operation of the pixel circuit from time T0 to T18 will be described below.

The recharge signal RCG is output at T0, T5, T9, T13, and T16 at a constant cycle. The count gate signal CNG is a signal that is usually in the OFF state and is a combination of pulse signals of different sampling phases in the same cycle as the recharge signal RCG. That is, the count gate signal CNG constitutes the first pulse with the constant cycle at signals TO, T5, T9, T13, and T16. Also, signals at T1, T7, T10, T14, and T17 constitute the second pulse with the constant cycle offset from TO. Further, signals at T4, T8, T11, T15, and T18 constitute the third pulse with the constant cycle offset from TO. As in some implementations described above, there are three phases of the counting, and one subframe is output by resetting three times. The counter 1510 performs the counting operation if the count gate signal CNG is High when the count gate 1508 is ON, i.e., the voltage V2 is High. Therefore, the counting operation is performed at the rise time of V3, i.e., at T4, T5, T7, T8, T9, and T13.

According to some implementations of the present disclosure, the number of bits of counters needed for one pixel is 4. Therefore, the number of bits of the plurality of counters in some implementations described above may be less than the total number of bits.

### Third Embodiment

An example third embodiment of the present disclosure can combine multiple pixel circuits.

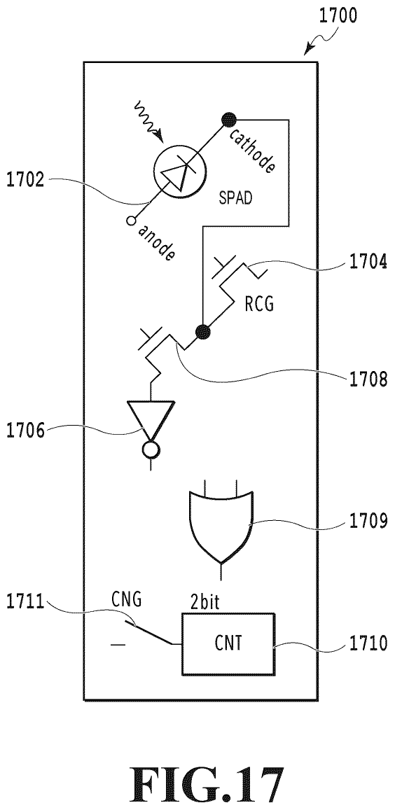

FIG. 17 illustrates components of one pixel circuit according to an implementation of the present disclosure. The pixel circuit 1700 includes an SPAD 1702, a recharge switch 1704 that controls the supply of the recharge signal RCG, a voltage control gate 1708, an inverter 1706, an OR circuit 1709, and a counter 1710. The voltage control gate 1708 is configured to control an input voltage of the inverter 1706. In some implementations of the present disclosure, a count gate 1711 functions as a gate part and the counter 1710 functions as a measuring part. In the following description, the number of bits of the counter is 2 bits for counting.

The OR circuit 1709 and the counter 1710 may be shared with other pixel circuits. Thus, the position at which the inverter 1706 and the OR circuit 1709 are connected is adaptively changed. Also, if the OR circuit 1709 or counter 1710 are shared, the OR circuit or counter included in other pixel circuit may not be used.

Some implementations of the present disclosure provides an example of a configuration of a pixel circuit in a set of 2×2 pixels. As the set of 2×2 pixels, the following read modes may be provided:
(1) 2×2 binning mode integrating 4 pixels
(2) 2×1 binning mode to integrate 2 pixels
(3) Full mode to read one pixel at a time
   In the following description, the configuration of the pixel circuit can be in accordance with some implementations described above.

The binning mode is a mode in which charges of a plurality of pixels are integrated to output as a single pixel to enhance sensitivity. In the following embodiment, the plurality of counters are connected in parallel, and the measuring part is configured to sum the count values from a plurality of photodiodes.

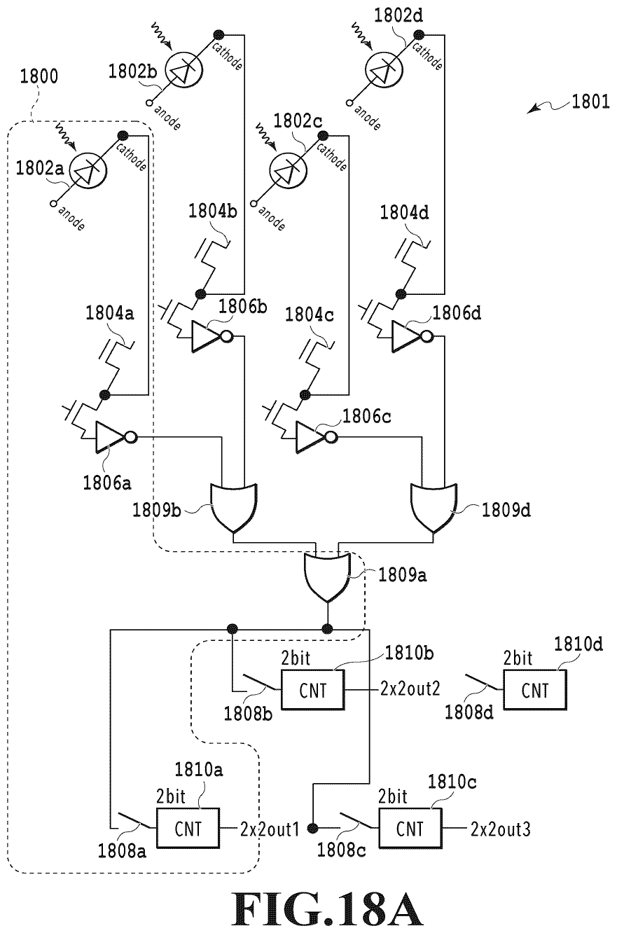

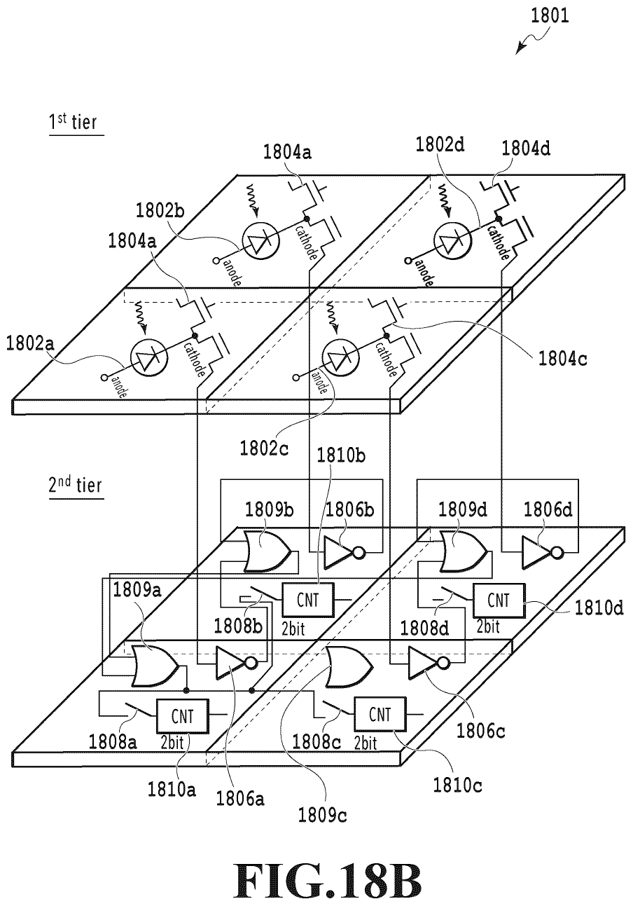

FIG. 18A illustrates an example configuration of a pixel circuit in mode (1). FIG. 18B also shows an example of the actual connection of the pixel circuit shown in FIG. 18A. A pixel circuit 1801 includes the first pixel circuit 1800 including an SPAD 1802a, a recharge switch 1804a, a count gate 1808a, an inverter 1806a, an OR circuit 1809a, and a counter 1810a. Similarly, the second pixel circuit includes an SPAD 1802b, a recharge switch 1804b, a count gate 1808b, an inverter 1806b, an OR circuit 1809b, and a counter 1810b. The third pixel circuit includes an SPAD 1802c, a recharge switch 1804c, a count gate 1808c, an inverter 1806c, an OR circuit 1809c, and a counter 1810c. Further, the fourth pixel circuit includes an SPAD 1802d, a recharge switch 1804d, a count gate 1808d, an inverter 1806d, an OR circuit 1809d, and a counter 1810d.

The inverter 1806a of the first pixel circuit and the inverter 1806b of the second pixel circuit are connected to the OR circuit 1809b. The inverter 1806c of the third pixel circuit and the inverter 1806d of the fourth pixel circuit are also connected to the OR circuit 1809d. Further, the outputs of the OR circuit 1809b and the OR circuit 1809d are connected to the OR circuit 1809a.

The OR circuit 1809a is connected in parallel to the counters 1810a, 1810b, and 1810c. The OR circuit 1809c and counter 1810d are not used in this example.

In FIG. 18B, the pixel circuit 1801 has a two-tier structure consisting of the first tier comprising SPADs 1802a-1802d and the second tier comprising counters 1810a-1810d. The first tier corresponds to the sensor substrate 302 shown in FIG. 3, and the second tier corresponds to the circuit board 400 shown in FIG. 4. In this example, the pulses of the count gate signal CNG are supplied three times for a single recharge signal RCG as in some implementations described above. As described above, the number of bits of the counter according to some implementations of the present disclosure is 2 bits for counting. Since the three counters are connected in parallel, the total number of bits for counting is 6 bits. For example, the counter 1810a may be configured to output upper two bits of the count value 2×2out1, the counter 1810b may be configured to output middle two bits of the count value 2×2out2, and the counter 1810c may be configured to output lower two bits of the count value 2×2out3. The 4-pixel signals are summed to generate one output.

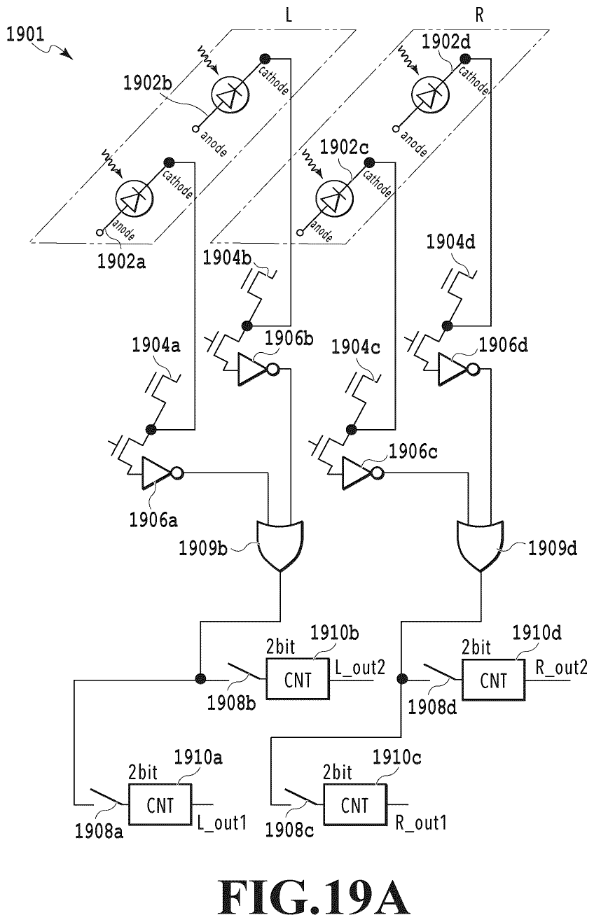

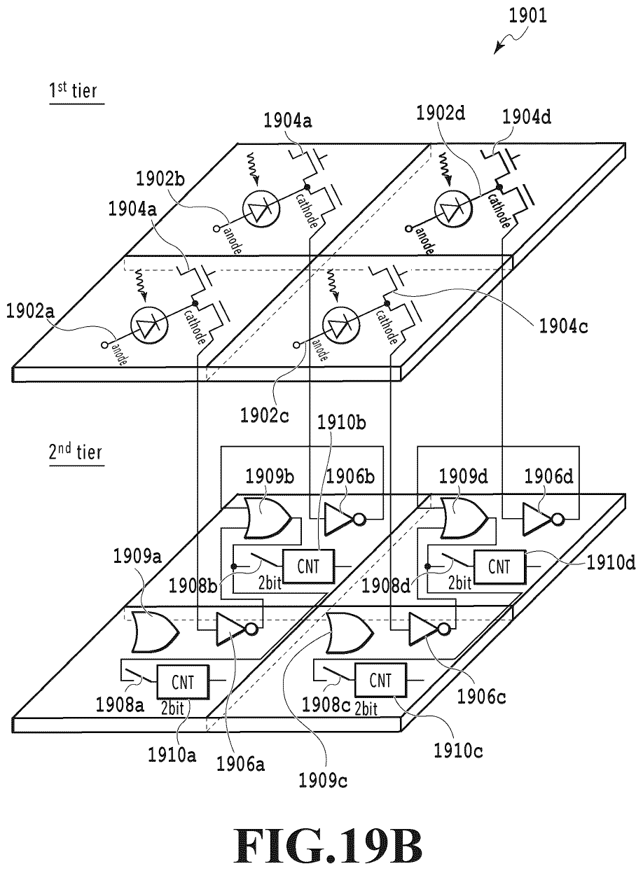

FIG. 19A illustrates an example configuration of mode (2). FIG. 19B also shows an example of the actual connection of the pixel circuit shown in FIG. 19A. In the pixel circuit 1901, the first pixel circuit includes an SPAD 1902a, a recharge switch 1904a, a count gate 1908a, an inverter 1906a, an OR circuit 1909a, and a counter 1910a. Similarly, the second pixel circuit includes an SPAD 1902b, a recharge switch 1904b, a count gate 1908b, an inverter 1906b, an OR circuit 1909b, and a counter 1910b. The third pixel circuit includes an SPAD 1902c, a recharge switch 1904c, a count gate 1908c, an inverter 1906c, an OR circuit 1909c, and a counter 1910c. Further, the fourth pixel circuit includes an SPAD 1902d, a recharge switch 1904d, a count gate 1908d, an inverter 1906d, an OR circuit 1909d, and a counter 1910d.

The inverter 1906a of the first pixel circuit and the inverter 1906b of the second pixel circuit are connected to the OR circuit 1909b. The OR circuit 1909b is connected in parallel to the count gates 1908a and 1908b. The count gate 1908a is connected to the counter 1910a, which outputs a pixel signal L_out1. The count gate 1908b is connected to the counter 1910b, which outputs a pixel signal L_out2. For example, L_out1 can be a signal of upper two bits of a count value, and L_out2 can be a signal of lower two bits of a count value. The inverter 1906c of the third pixel circuit and the inverter 1906d of the fourth pixel circuit are also connected to the OR circuit 1909d. Further, the OR circuit 1909d is connected in parallel to the count gate 1908c and the count gate 1908c. The count gate 1908c is connected to the counter 1910c, which outputs a pixel signal R_out1. The count gate 1908d is connected to the counter 1910d, which outputs a pixel signal R_out2. For example, R_out1 can be a signal of the upper two-bit count value, and R_out2 can be a signal of the lower two-bit count value. The OR circuits 1909a and 1909c are not used in this example.

In FIG. 19B, the pixel circuit 1901 has a two-tier structure consisting of the first tier comprising SPADs 1902a-1902d and the second tier comprising counters 1910a-1910d. In this example, the count gate signal CNG pulse is twice relative to the recharge signal RCG. The counter count bits are a total of 4 bits. The two-pixel signal is summed to generate one output.

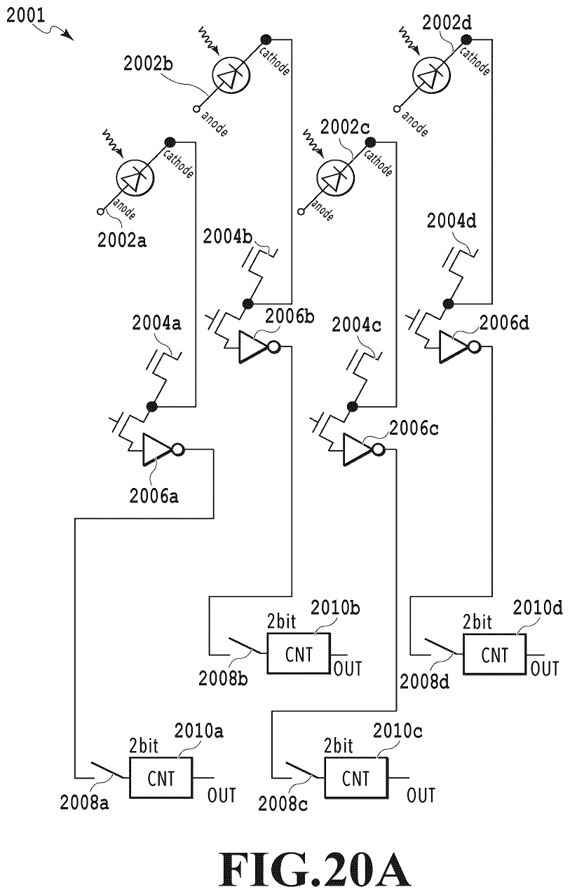

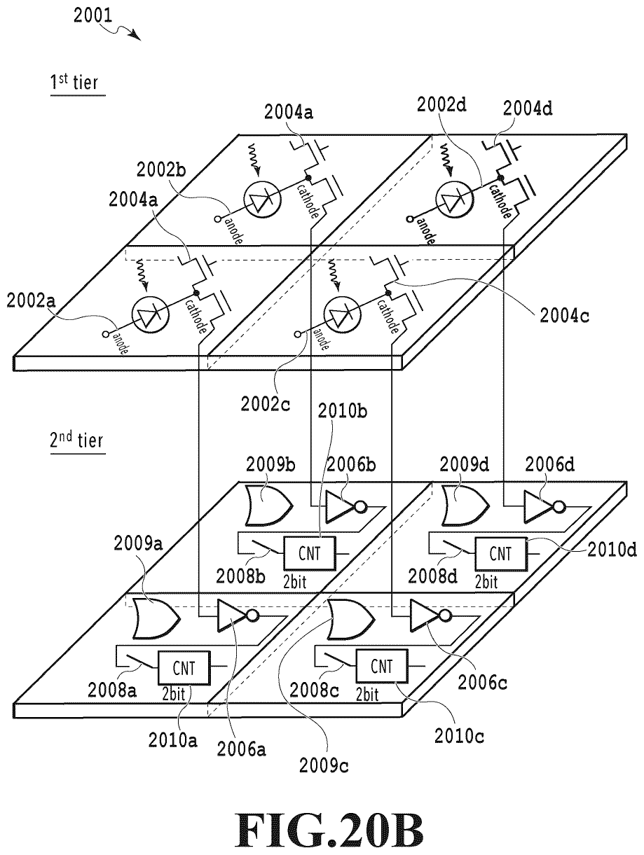

FIG. 20A illustrates an example configuration of mode (3). FIG. 20B also shows an example of the actual connection of the pixel circuit shown in FIG. 20A. In the pixel circuit 2001, the first pixel circuit includes an SPAD 2002a, a recharge switch 2004a, a count gate 2008a, an inverter 2006a, an OR circuit 2009a, and a counter 2010a. Similarly, the second pixel circuit includes an SPAD 2002b, a recharge switch 2004b, a count gate 2008b, an inverter 2006b, an OR circuit 2009b, and a counter 2010b. The third pixel circuit includes an SPAD 2002c, a recharge switch 2004c, a count gate 2008c, an inverter 2006c, an OR circuit 2009c, and a counter 2010c. Further, the fourth pixel circuit includes an SPAD 2002d, a recharge switch 2004d, a count gate 2008d, an inverter 2006d, an OR circuit 2009d, and a counter 2010d.

In this example, four OR circuits 2009a-2009d are not used. Thus, the inverters 2006a-2006d are connected to the counters 2010a-2010d, respectively.

In FIG. 20B, the pixel circuit 2001 has a two-tier structure consisting of the first tier including SPAD 2002a-2002d and the second tier including counters 2010a-2010d. In this example, the pulse of the count gate signal CNG is once for a single recharge signal RCG, and the number of bits of the counter is 2 bits.

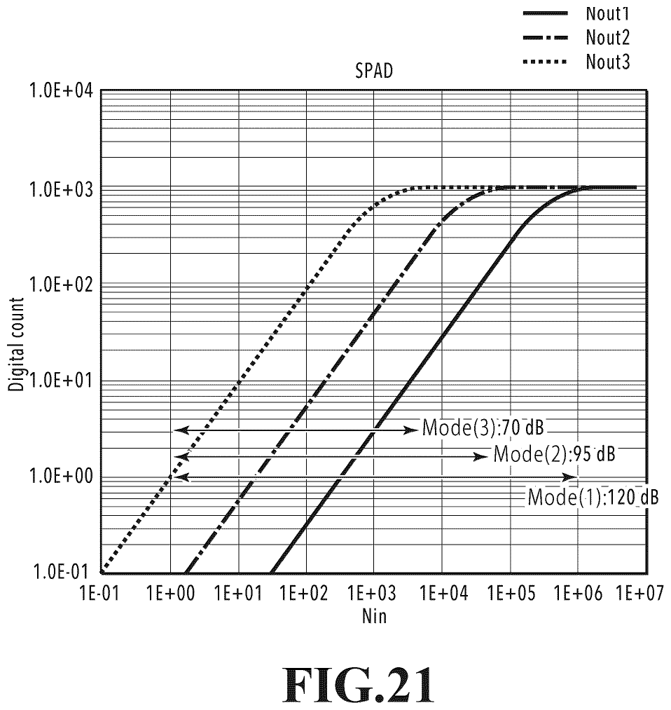

FIG. 21 shows the dynamic range of the image sensor using pixel circuits according to modes (1) to (3). In the case of mode (1), three times the count gate signal CNG is output for one recharge signal RCG. Thus, the dynamic range becomes wide until three curves in FIG. 21 reach a maximum saturation amount, i.e., 120 dB. In the case of mode (2), the number of count gate signal CNGs is doubled for one recharge signal RCG. Thus, the dynamic range is the width until the two curves in FIG. 21 reach the maximum saturation amount, i.e., about 95 dB. In the case of mode (3), the count gate signal CNG is once for each recharge signal RCG. Thus, the dynamic range is the width until one curve of FIG. 21 reaches the maximum saturation amount, i.e., about 70 dB.

As described above, according to some implementations of the present disclosure, a plurality of binning modes can be created by switching connection of circuit elements included in the pixel circuit. Accordingly, the sensitivity and resolution can be freely switched depending on the imaging conditions.

The pixel circuits according to the above-described embodiments can configure an image sensor arranged in a two-dimensional lattice.

In addition, the pixel circuits and image sensors described in the above-described embodiments can be applied to imaging devices mounted on various devices such as digital cameras, mobile phones, in-vehicle cameras, and the like.

The foregoing descriptions are merely specific implementation manners of the present disclosure, but are not intended to limit the protection scope of the present disclosure. Any variation or replacement readily figured out by a person skilled in the art within the technical scope disclosed shall fall within the protection scope of the present disclosure. Therefore, the protection scope of the present disclosure shall be subject to the protection scope of the claims.

1. A pixel circuit, comprising:
a photodiode;
a measuring circuit configured to measure a light amount in accordance with a current output from one end of the photodiode; and
a gate circuit provided between the photodiode and the measuring circuit,
wherein:
a recharge signal is supplied to set one end of the photodiode to a predetermined potential; and
the gate circuit is configured to connect the photodiode and the measuring circuit such that the measuring circuit measures the light amount at a plurality of time points in a single cycle of the recharge signal.

2. The pixel circuit according to claim 1, wherein the gate circuit is configured to connect the photodiode and the measuring circuit at the same cycle as a cycle of the recharge signal.

3. The pixel circuit according to claim 1, wherein the gate circuit is configured to connect the photodiode and the measuring circuit at a sampling phase different from the recharge signal.

4. The pixel circuit according to claim 1, wherein the measuring circuit includes a plurality of counters, and the gate circuit is configured to connect the photodiode and each of the plurality of counters such that the plurality of counters perform counting operations at different points in time.

5. The pixel circuit according to claim 4, wherein the gate circuit comprises a plurality of switches, and wherein each of the plurality of switches is configured to connect the photodiode and one of the plurality of counters.

6. The pixel circuit according to claim 4, wherein the plurality of counters is configured to output a count value after the recharge signal is supplied multiple times.

7. The pixel circuit according to claim 1, wherein the measuring circuit is configured to sum count values from a plurality of photodiodes to generate one output.

8. An image sensor comprising pixel circuits that are arranged in a two-dimensional lattice, wherein the pixel circuit comprises:
a photodiode;
a measuring circuit configured to measure a light amount in accordance with a current output from one end of the photodiode; and
a gate circuit provided between the photodiode and the measuring circuit,
wherein:
a recharge signal is supplied to set one end of the photodiode to a predetermined potential; and
the gate circuit is configured to connect the photodiode and the measuring circuit such that the measuring circuit measures the light amount at a plurality of time points in a single cycle of the recharge signal.

9. The image sensor according to claim 8, wherein the gate circuit is configured to connect the photodiode and the measuring circuit at the same cycle as a cycle of the recharge signal.

10. The image sensor according to claim 8, wherein the gate circuit is configured to connect the photodiode and the measuring circuit at a sampling phase different from the recharge signal.

11. The image sensor according to claim 8, wherein the measuring circuit includes a plurality of counters, and the gate circuit is configured to connect the photodiode and each of the plurality of counters such that the plurality of counters perform counting operations at different points in time.

12. The image sensor according to claim 11, wherein the gate circuit comprises a plurality of switches, and wherein each of the plurality of switches is configured to connect the photodiode and one of the plurality of counters.

13. The image sensor according to claim 11, wherein the plurality of counters is configured to output a count value after the recharge signal is supplied multiple times.

14. The image sensor according to claim 8, wherein the measuring circuit is configured to sum count values from a plurality of photodiodes to generate one output.

15. A method of operating a pixel circuit comprising a photodiode, a measuring circuit, and a gate circuit provided between the photodiode and the measuring circuit, the method comprising:
supplying a recharge signal to one end of the photodiode to set the one end to a predetermined potential; and
connecting, via the gate circuit, the photodiode and the measuring circuit such that the measuring circuit measures a light amount at a plurality of time points within a single cycle of the recharge signal.

16. The method according to claim 15, wherein connecting the photodiode and the measuring circuit is performed at a same cycle as a cycle of the recharge signal.

17. The method according to claim 15, wherein connecting the photodiode and the measuring circuit is performed at a sampling phase different from a phase of the recharge signal.

18. The method according to claim 15, wherein the measuring circuit includes a plurality of counters, and connecting the photodiode and the measuring circuit comprises connecting the photodiode to each of the plurality of counters such that the plurality of counters perform counting operations at different points in time.

19. The method according to claim 18, wherein the gate circuit comprises a plurality of switches, and connecting the photodiode to each of the plurality of counters is performed by controlling each of the plurality of switches to connect the photodiode to a respective one of the plurality of counters.

20. The method according to claim 18, further comprising:
outputting a count value from the plurality of counters after the recharge signal has been supplied a plurality of times.
